(19) United States
(12) Patent Application Publication
(10) Pub. No.: US 2025/0242389 A1
(43) Pub. Date: Jul. 31, 2025

(54) CLEANING APPARATUS, PROCESSING SYSTEM, AND CLEANING METHOD

(71) Applicant: DISCO CORPORATION, Tokyo (JP)

(72) Inventor: Atsushi KUNIHARA, Tokyo (JP)

(73) Assignee: DISCO CORPORATION, Tokyo (JP)

(21) Appl. No.: 19/034,957

(22) Filed: Jan. 23, 2025

(30) Foreign Application Priority Data
Jan. 30, 2024 (JP) 2024-012044

(51) Int. Cl. B08B 3/04; B05C 21/00; B23K 26/70; H01L 21/67

(52) U.S. Cl. CPC B08B 3/041; B23K 26/70; B05C 21/00; H01L 21/67051

(57) ABSTRACT

A cleaning apparatus comprises a first holder surface which is for holding a first surface of a workpiece and is smaller than the workpiece, a rotation device configured to support and rotate the first holder surface, a protruding portion which is located closer than the first holder surface to the rotation device and protrudes outward with respect to the first holder surface, and a nozzle configured to supply cleaning fluid toward the protruding portion. The protruding portion is configured to guide the cleaning fluid supplied from the nozzle to enter a gap between the protruding portion and the first surface of the workpiece exposed off the first holder surface to clean an outer periphery of the first surface of the workpiece.

### CROSS REFERENCE TO RELATED APPLICATION

This application is based upon and claims the benefit of priority from the prior Japanese Patent Application No. 2024-012044, filed on Jan. 30, 2024; the entire contents of which are incorporated herein by reference.

### FIELD

The present disclosure relates to a cleaning apparatus, a processing system including the cleaning apparatus, and a cleaning method.

### BACKGROUND

Conventionally, a cleaning apparatus that may clean a workpiece having been processed through, for example, machining or coating with a protective layer is known. The cleaning apparatus may generally be configured, as disclosed in, for example, Japanese Patent Laid-Open Publication No. 2014-038991 and Japanese Patent Laid-Open Publication No. 2007-201178, to clean the workpiece by holding one side of the workpiece on a holder table and supplying a cleaning fluid to the other exposed side of the workpiece.

However, in a peripheral area of the workpiece, dirt may often adhere on the one side, by which the holder table holds the workpiece, as well as the other exposed side, during a pre-cleaning process and the cleaning process. In relation to such a technical problem, for example, Japanese Patent Laid-Open Publication No. 2013-125872 discloses a cleaning apparatus configured to supply fluid toward a peripheral area of a workpiece from a nozzle located below a holder surface, and, for another example, No. 2012-064872 discloses a cleaning apparatus configured to supply fluid toward a back surface of a workpiece from a nozzle located below a holder surface.

The cleaning apparatuses configured as above with the nozzle located below the holder surface may likely be structurally constrained due to limited space inside the cleaning apparatuses, and designing of those cleaning apparatuses may not be easy.

### SUMMARY

In view of the problem, the present disclosure is directed to provide a workpiece cleaning technique that enables cleaning of a surface of the workpiece on a side toward a holder surface.

According to an aspect of the present disclosure, a cleaning apparatus, comprises a first holder surface for holding a first surface of a workpiece, the first holder surface being smaller than the workpiece; a rotation device configured to support and rotate the first holder surface; a protruding portion located closer than the first holder surface to the rotation device, the protruding portion protruding outward with respect to the first holder surface; and a nozzle configured to supply cleaning fluid toward the protruding portion. The protruding portion is configured to guide the cleaning fluid supplied from the nozzle to enter a gap between the protruding portion and the first surface of the workpiece exposed off the first holder surface to clean an outer periphery of the first surface of the workpiece.

According to another aspect of the present disclosure, a processing system comprises the cleaning apparatus as described above; a coating unit having a second holder surface, the second holder surface being smaller than the workpiece and configured to hold the first surface of the workpiece, the coating unit being configured to supply a coating agent to a second surface of the workpiece held by the second holder surface and coat the second surface of the workpiece; and a processing unit configured to process the workpiece, the second surface of which is coated by the coating unit. The cleaning apparatus is configured to clean the workpiece having been processed by the processing unit, and the first holder surface of the cleaning apparatus is smaller than the second holder surface of the coating unit.

According to another aspect of the present disclosure, a cleaning method to clean the workpiece with use of the cleaning apparatus as described above comprises a holding step to hold the first surface of the workpiece on the first holder surface and an outer periphery cleaning step to supply the cleaning fluid from the nozzle to the protruding portion and clean the outer periphery of the first surface of the workpiece exposed off the first holder surface.

### BRIEF DESCRIPTION OF DRAWINGS

FIG. 1 is a perspective view of the laser processing apparatus according to an embodiment of the present disclosure.

FIG. 2 is a diagram to illustrate a configuration of the coating unit.

FIG. 3 is a diagram to illustrate a configuration of a conveyer unit in an edge-clamp style.

FIG. 4 is a diagram to illustrate a cleaning unit cleaning a front surface.

FIG. 5 is a diagram to illustrate the cleaning unit cleaning a back surface.

FIG. 6 illustrates an exemplary nozzle movement in the cleaning unit.

FIG. 7 illustrates a modified example of the cleaning unit cleaning the back surface.

### DESCRIPTION OF EMBODIMENTS

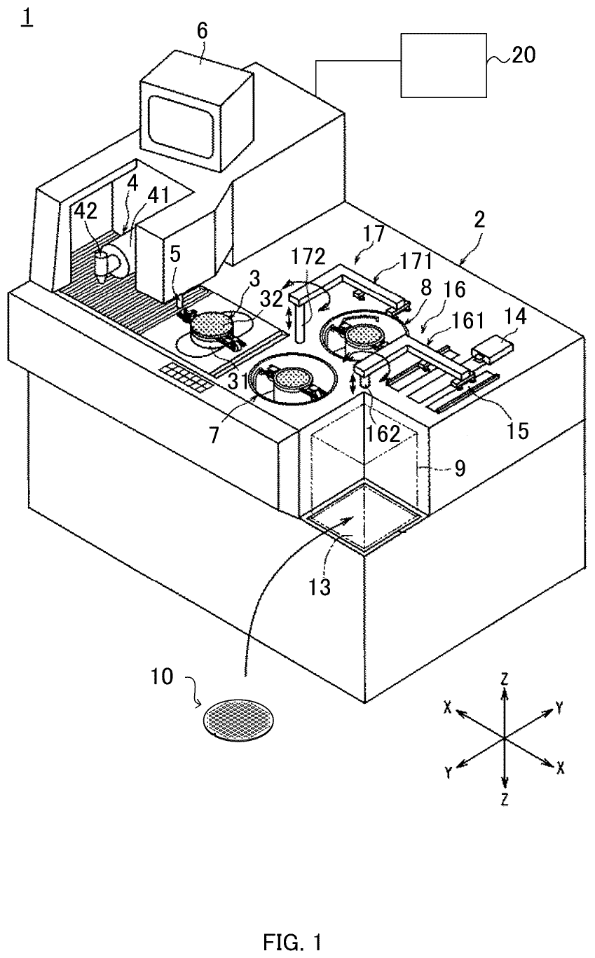

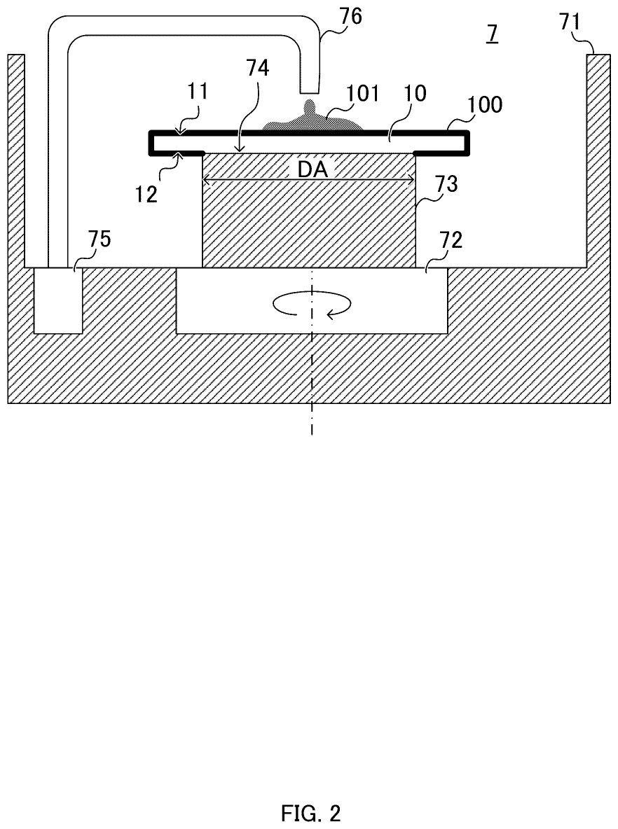

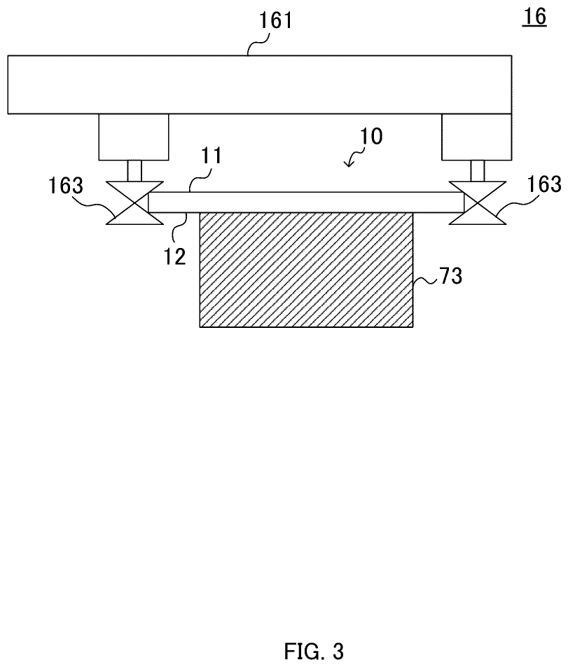

FIG. 1 is a perspective view of a laser processing apparatus 1 according to the embodiment of the present disclosure. FIG. 2 is a diagram to illustrate a configuration of a coating unit 7 provided in the laser processing apparatus 1. FIG. 3 is a diagram to illustrate a configuration of a conveyer unit 16 in an edge-clamp style provided in the laser processing apparatus 1. Hereinbelow, with reference to FIGS. 1-3, the laser processing apparatus 1 will be described.

The laser processing apparatus 1 shown in FIG. 1 forms a processing system to process a workpiece 10. The laser processing apparatus 1 may process the workpiece 10 taken out from a cassette 9 with a laser unit 4 and stow the processed workpiece 10 in the cassette 9. An X-axis direction and a Y-axis direction shown in FIG. 1 are horizontal directions, and the X-axis direction and the Y-axis direction are orthogonal to each other. A Z-axis direction is a vertical direction.

The workpiece 10 being an object to be processed in the laser processing apparatus 1 is a disk-shaped wafer formed of a material such as silicon, sapphire, or gallium, on which electric devices are formed in areas partitioned in grid by a plurality of divider lines.

However, the type, the material, and the shape of the workpiece 10 are not necessarily limited. For example, the workpiece 10 may be a rectangular package substrate. Moreover, the workpiece 10 are not necessarily limited to the wafer with the electric devices formed thereon or the package substrate but may be a wafer before the devices are formed thereon or other substrate or a board.

The laser processing apparatus 1 includes, as shown in FIG. 1, a housing 2 in a form of substantially rectangular parallelepiped, a chuck table 3, a laser unit 4, an image-capturing unit 5, a display 6, a coating unit 7, a cleaning unit 8, a lifting stage 13, a temporary placement table 15, a plurality of conveyer units (conveyer unit 14, conveyer unit 16, and conveyer unit 17), and a control unit 20.

The chuck table 3 is a table to hold the workpiece 10 and is used when the workpiece 10 is processed by the laser unit 4. The chuck table 3 includes a supporting base 31 and a suction chuck 32 fixed to the supporting base 31. The supporting base 31 is configured to be rotated about a rotating shaft, which extends in the Z-axis direction, by a rotation device which is not shown. The suction chuck 32 is made of a porous material and has a suction-holder surface, on which the workpiece 10 may be suctioned and held thereon.

The chuck table 3 includes a flow path formed between a suction source, which is not shown, and a lower surface of the suction chuck 32. By operating the suction source, the chuck table 3 may cause a suction force to act on the suction-holder surface through the suction chuck 32. The chuck table 3 may hold the workpiece 10 by suctioning the workpiece 10 placed on the suction-holder surface.

On the chuck table 3, the workpiece 10 may be turned into a desired direction by rotating the supporting base 31 with the rotation device. Moreover, the chuck table 3 is movable in the X-axis direction and the Y-axis direction by a moving device, which is not shown. In particular, the chuck table 3 may move in the X-axis direction and thereby move back and force among at least a draw in/out position, at which the workpieces 10 may be passed between the conveyer unit 17 and the chuck table 3, an image-capturing position, at which the image capturing unit 5 may capture an image of the workpiece 10, and a processing position, at which the laser unit 4 may process the workpiece 10. Moreover, the chuck table 3 may move in the Y-axis direction and thereby move a point on the workpiece 10 at which a laser beam is emitted in the Y-axis direction.

FIG. 1 shows the suction chuck 32 in a round shape; however, the shape of the suction chuck on the chuck table 3 is not necessarily limited to round, but the suction chuck may be, for example, in a rectangular shape.

The laser unit 4 is an example of the processing unit for processing the workpiece 10. The laser unit 4 includes a casing 41 and a condenser 42. The laser unit 4 may process the workpiece 10 by condensing laser light from a pulse laser oscillator, which is not shown, housed in the casing 41 with the condenser 42 and casting the condensed light at the workpiece 10 held on the chuck table 3. The laser unit 4 may, for example, form cutter grooves along the divider lines on the workpiece 10.

The image-capturing unit 5 is a unit to capture an image of the workpiece 10. The image capturing unit 5 includes an image-capturing optical system and image-capturing elements. Signals of the image of the workpiece 10 captured by the image-capturing unit 5 are transmitted to the control unit 20. The control unit 20 processes the image signals transmitted from the image-capturing unit 5 and generates image data. The control unit 20 may refer to image information included in the image data and control behaviors of the laser processing apparatus 1. For example, the control unit 20 may adjust relative positions between the workpiece 10 and the laser unit 4 based on the image information obtained prior to the laser processing so that the laser light may be emitted at the divider lines.

The display 6 is a displaying apparatus such as a liquid crystal display and may display and provide information to an operator of the laser processing apparatus 1. The display 6 may display, for example, the image of the workpiece 10 captured by the image-capturing unit 5 to allow the operator to examine a condition of the workpiece 10 before or after the processing.

The coating unit 7 is a unit to coat the workpiece 10 with a protective layer. The coating unit 7 includes, as shown in FIG. 2, a spinner table 73 having a holder surface 74 to hold a surface 12 of the workpiece 10, a nozzle 76 to supply liquid resin 101 being a coating agent to the workpiece 10 held on the spinner table 73, and rotation devices (rotation device 72, rotation device 75), which are accommodated in a body 71. The spinner table 73 and the nozzle 76 are rotatable by the rotation device 72 and the rotation device 75, respectively. The holder surface 74 is a suction-holder surface, on which the workpiece 10 is suctioned and held with use of a negative pressure generated by a suctioning act of a suction source (not shown).

The coating unit 7 causes the workpiece 10 held on the spinner table 73 to rotate with the rotation device 72 and drips the liquid resin 101 to supply the liquid resin 101 from the nozzle 76 onto an upper surface (surface 11) of the workpiece 10. The liquid resin 101 dripping on the upper surface (surface 11) of the workpiece 10 spreads over the upper surface (surface 11) of the workpiece 10 due to a centrifugal force and forms a protective layer 100 and coats the workpiece 10.

The liquid resin 101 supplied by the coating unit 7 is a water-soluble resin, and the protective layer 100 is formed of the cured liquid resin 101. In other words, the coating unit 7 supplies the liquid resin 101 to the upper surface (surface 11) of the workpiece 10 held on the holder surface 74 and coats the upper surface (surface 11) of the workpiece 10 with the liquid resin 101. Moreover, the holder surface 74 of the spinner table 73 has a diameter (diameter DA) smaller than the workpiece 10. Therefore, in the coating unit 7, the workpiece 10 is held by the spinner table 73 in a state where a part of the workpiece 10 protrudes outward from the holder surface.

The cleaning unit 8 is a cleaning apparatus to clean the workpiece 10. The cleaning unit 8 includes a spinner table for holding the workpiece 10 and a nozzle to supply cleaning fluid to the workpiece 10 held on the spinner table. The cleaning unit 8 may clean the workpiece 10 by rotating the workpiece 10 held on the spinner table and supplying the cleaning fluid from the nozzle to the workpiece 10. The cleaning unit 8 is configured to clean an outer periphery on the back surface of the workpiece 10. The configuration to clean the outer periphery on the back surface of the workpiece 10 will be described later in detail.

The cleaning fluid to be supplied from the cleaning unit 8 is not necessarily limited but may be, for example, water. Optionally, the cleaning fluid may be mixture of two fluids including water and air. Moreover, the cleaning unit 8 may be equipped with a nozzle to supply the air additionally to the nozzle to supply the cleaning fluid. The cleaning unit 8 may supply the air to the cleaned workpiece 10 to promote the cleaned workpiece 10 to dry faster.

The cassette 9 has a plurality of storages tiered in the Z-axis direction to store the workpieces 10. The cassette 9 has an opening, through which workpieces 10 are drawn in or out from the storages, and is mounted on the lifting stage 13 with the opening orienting the conveyer unit 14, which will be described further below. In the laser processing apparatus 1, by lifting or lowering the lifting stage 13, the cassette 9 may move in the Z-axis direction with respect to the conveyer unit 14, and thereby one of the workpieces 10 stored in the cassette 9 may be drawn in or out from the storage by the conveyer unit 14.

The temporary placement table 15 is a temporary placement area where one of the workpieces 10 to be drawn in or out from the cassette 9 is temporarily placed and includes a pair of guide rails arranged along the Y-axis direction. A distance between the pair of guide rails is adjustable by an adjusting device, which is not shown, so that the distance may be adjusted in accordance with a size (diameter, size) of the workpiece 10 when the workpiece 10 is placed on the temporary placement table 15.

The conveyer unit 14 is a unit to convey the workpiece 10 in the laser processing apparatus 1. The conveyer unit 14 includes a clamp part to clamp one end of the workpiece 10 and may convey the workpiece 10 between the cassette 9 and the temporary placement table 15 by moving the clamp part clamping the workpiece 10.

The conveyer unit 16 is a unit to convey the workpiece 10 in the laser processing apparatus 1. The conveyer unit 16 includes a conveyer arm 161 and a shaft 162, about which the conveyer arm 161 is rotatable. The conveyer arm 161 may be equipped with, for example, a pair of clamps 163 that may clamp ends of the workpiece 10 as shown in FIG. 3. The conveyer unit 16 may convey the workpiece 10 from the temporary placement table 15 to the coating unit 7 or from the cleaning unit 8 to the temporary placement table 15 by rotating the shaft 162, along with the pair of clamps 163 clamping the workpiece 10, and as such moving the conveyer arm 161.

The conveyer unit 17 is a unit to convey the workpiece 10 in the laser processing apparatus 1. The conveyer unit 17 includes a conveyer arm 171 and a shaft 172, about which the conveyer arm 171 is rotatable. The conveyer arm 171 is equipped with a suction pad to suction and hold the workpiece 10. The conveyer arm 171 may convey the workpiece 10 from the coating unit 7 to the chuck table 3 or from the chuck table 3 to the cleaning unit 8 by rotating the shaft 172, with the suction pad suctioning and holding the workpiece 10 thereon, and as such moving the conveyer arm 171.

The control unit 20 controls each part of the laser processing apparatus 1 to cause the laser processing apparatus 1 to perform operations including a processing operation and a cleaning operation. The control unit 20 is a computer including an arithmetic processing device such as a CPU (Central Processing Unit), a memory device such as ROM (Read Only Memory) and RAM (Random Access Memory), and an input/output interface connected to each part of the laser processing apparatus 1. The arithmetic processing device in the control unit 20 may perform arithmetic processes according to programs stored in the memory device and output controlling signals for controlling the laser processing apparatus 1 to each part of the laser processing apparatus 1 through the input/output interface. Moreover, signals detected in each part of the laser processing apparatus 1 may be input to the control unit 20 through the input/output interface.

The laser processing apparatus 1 configured as above may, in order to prevent debris produced during laser-processing from adhering to a device surface of the workpiece 10, coat the workpiece 10 with the protective layer 100 by the coating unit 7 and thereafter form the cutter grooves on the workpiece 10 with the laser unit 4. Thereafter, the laser processing apparatus 1 may clean the workpiece 10 having been processed with the laser unit 4 in the cleaning unit 8 and remove the debris together with the protective layer 100. In other words, in the laser processing apparatus 1, the laser unit 4 processes the workpiece 10, of which surface 11 is coated with the protective layer by the coating unit 7, and the cleaning unit 8 cleans the workpiece 10 having been processed by the laser unit 4.

More specifically, in the laser processing apparatus 1, first, the conveyer unit 14 places the workpiece 10 drawn out from the cassette 9 on the temporary placement table 15. The workpiece 10 placed on the temporary placement table 15 is conveyed by the conveyer unit 16 to the coating unit 7. In the coating unit 7, the workpiece 10 is coated with the protective layer 100 and thereafter conveyed by the conveyer unit 17 to the chuck table 3. The chuck table 3 receiving the workpiece 10 from the conveyer unit 17 moves the workpiece 10 to a position straight below the laser unit 4.

The workpiece 10 moved to the position straight below the laser unit 4 is processed through a cutting operation by the laser unit 4. The processed workpiece 10 is moved to the draw-in/out position again by the chuck table 3 and conveyed by the conveyer unit 17 from the draw-in/out position to the cleaning unit 8. In the cleaning unit 8, the workpiece 10 is cleaned with the cleaning fluid. The workpiece 10 cleaned with the cleaning fluid is conveyed by the conveyer unit 16 to the temporary placement table 15 and thereafter stowed by the conveyer unit 14 in the cassette 9.

In the meantime, when the conveyer unit 16 of the edge-clamp style as shown in FIG. 3 is used, it is preferable that the diameters of the tables at the origin and the destination of the conveyance are smaller than a diameter of the workpiece 10. This is because, if the diameters of the tables are larger than the diameter of the workpiece 10, it may be difficult to clamp the workpiece 10 placed on the table by the edges. Moreover, for a table such as the spinner table that may rotate at relatively high speeds, in order to reduce the moment of inertia, it is preferable that the diameter of the table is smaller. For these reasons, processing devices may often employ tables with diameters smaller than the workpiece 10. Therefore, in the laser processing apparatus 1, the coating unit 7 and the cleaning unit 8 have the tables (spinner table 73, spinner table 83), of which diameters are smaller than the diameter of the workpiece 10.

However, with the tables having the smaller diameters, it may be likely that the dirt adheres to the back surface of the workpiece 10. This is because, when the workpiece 10 is held by the holder surface, a part of the workpiece 10 may protrude outward, and a part of the back surface (surface being held by the holder surface) of the workpiece 10, as well as the front surface, are exposed.

In this context, the back surface refers to the surface, by which the workpiece 10 is held by the holder surface of the table, in particular, in the example shown in FIG. 2, the surface 12 held by the holder surface 74. On the other hand, the front surface refers to the surface opposite to the surface by which the workpiece 10 is held by the holder surface of the table, in particular, in the example shown in FIG. 2, the surface 11 on the side opposite to the surface 12 by which the workpiece 10 is held by the holder surface 74.

Moreover, if the diameter of the spinner table 73 of the coating unit 7 is smaller than the workpiece 10, the liquid resin 101 spreading on the surface 11 as shown in FIG. 2 may reach the surface 12 beyond the outer periphery of the workpiece 10. As a result, the protective layer 100 may be formed not only on the front surface (surface 11) of the workpiece 10 but also undesirably on the outer periphery and the back surface (surface 12) of the workpiece 10.

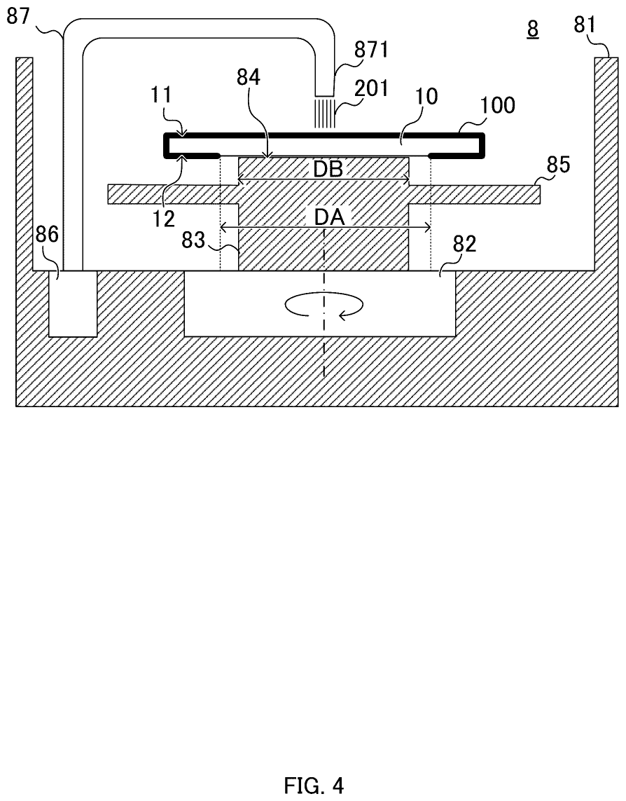

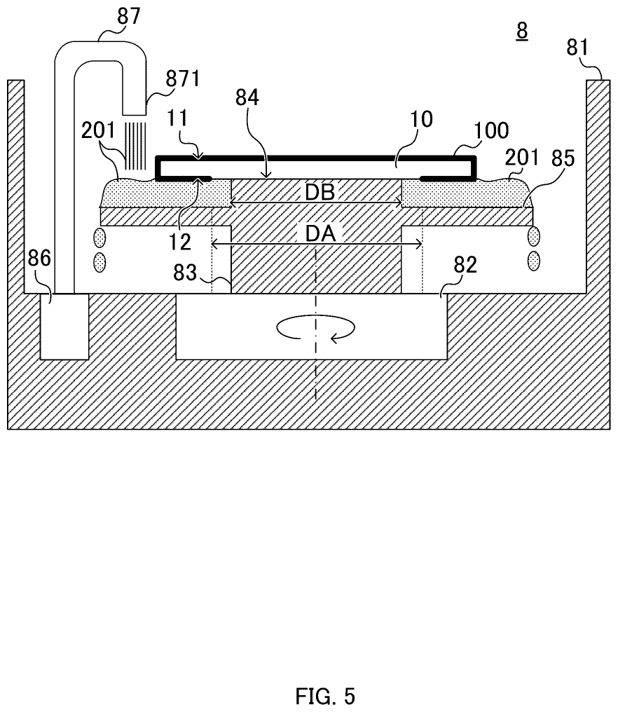

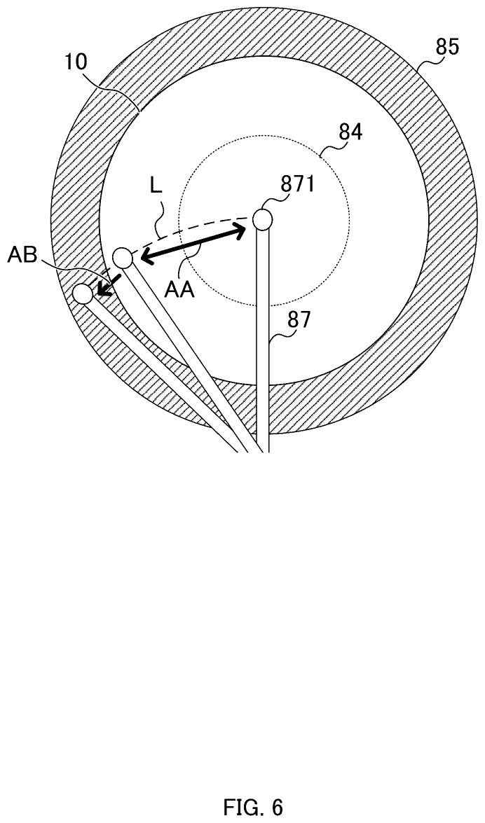

In consideration of these circumstances, in order to remove the dirt adhered to the back surface of the workpiece 10 and the protective layer 100 formed on the back surface of the workpiece 10, the cleaning unit 8 in the laser processing apparatus 1 is provided with a function to clean the back surface of the workpiece 10. FIG. 4 illustrates the cleaning unit cleaning the front surface. FIG. 5 illustrates the cleaning unit cleaning the back surface. FIG. 6 is a diagram to illustrate exemplary movement of the nozzle in the cleaning unit. Hereinafter, with reference to FIGS. 4-6, the cleaning unit 8 will be described in detail.

The cleaning unit 8 includes, as shown in FIGS. 4 and 5, a rotation device 82, the spinner table 83, a rotation device 86, and a nozzle 87, which are housed in a body 81. The rotation device 82 is a device to rotate the spinner table 83 and is a device to support and rotate the holder surface 84. The rotation device 86 is a device to rotate the nozzle 87.

The spinner table 83 includes the holder surface 84 to hold the surface 12 of the workpiece 10 and a protruding portion 85 located closer than the holder surface 84 to the rotation device 82. The surface 12 is an example of the first surface of the workpiece 10. The holder surface 84 is smaller than the workpiece 10 and is smaller than the holder surface 74 (second holder surface) of the spinner table 73 in the coating unit 7. More specifically, a diameter DB of the holder surface 84 is smaller than the diameter of the workpiece 10 and is smaller than the diameter DA of the holder surface 74 of the spinner table 73.

The protruding portion 85 is formed to protrude outward with respect to the holder surface 84. More specifically, the protruding portion 85 has a flange structure that protrudes outward from a sideward surface of the spinner table 83 having the holder surface 84 smaller than the workpiece 10 and protrudes outward farther than the workpiece 10. The nozzle 87 may supply the cleaning fluid 201 to the workpiece 10.

In the cleaning unit 8 configured as above, in the state where the workpiece 10 is held on the holder surface 84, as shown in FIGS. 4 and 5, the sideward surface of the spinner table 83, the upper surface of the protruding portion 85 and the surface 12 of the workpiece 10 protruding outward from the holder surface 84 form a recess portion between the workpiece 10 and the protruding portion 85. The cleaning unit 8 may use this recess portion to clean the back surface (surface 12) of the workpiece 10.

For cleaning the surface 11 of the workpiece 10, as shown in FIG. 4, the cleaning unit 8 locates the nozzle 87 above the workpiece 10 which is rotated by the rotation device 82. Moreover, the cleaning unit 8 supplies the cleaning fluid 201 from an end 871 of the nozzle 87 toward the surface 11 of the workpiece 10. More specifically, as shown in FIG. 6, the cleaning unit 8 cleans the surface 11 of the workpiece 10 by operating the rotation device 86 to move the end 871 of the nozzle 87 to reciprocate between a center and the outer periphery of the workpiece 10 as indicated by an arrow AA in FIG. 6 and supplying the cleaning fluid 201 toward the surface 11 of the rotating workpiece 10.

On the other hand, for cleaning the surface 12 of the workpiece 10, as shown in FIG. 5, the cleaning unit 8 operates the rotation device 86 to locate the nozzle 87 above the protruding portion 85 of the spinner table 83. More specifically, the cleaning unit 8 locates the end 871 of the nozzle 87 at a position outside the workpiece 10 and above the protruding portion 85 as indicated by an arrow AB shown in FIG. 6 so that the cleaning fluid 201 being supplied to the protruding portion 85 may not be hindered by the workpiece 10. Thereafter, the cleaning unit 8 supplies the cleaning fluid 201 from the end 871 of the nozzle 871 toward the protruding portion 85.

In the state where the end 871 of the nozzle 87 is located at the position shown in FIG. 5, as the cleaning fluid 201 is supplied, the cleaning fluid 201 is guided by the protruding portion 85 to enter the recess portion (in other words, a gap between the protruding portion 85 and the surface 12 of the workpiece 10 exposed off the holder surface 84). When an amount of the cleaning fluid 201 being supplied is substantial, as shown in FIG. 5, the workpiece 10 and the protruding portion 85 rotate with respect to the nozzle 87 with the recess portion being filled with the cleaning fluid 201. Accordingly, the outer periphery of the surface 12 exposed off the holder surface 84 is cleaned by the cleaning fluid 201 filling the recess portion. Furthermore, depending on an amount of the flow of the cleaning fluid 201, the outer peripheral surface (an edge connecting the surface 11 and the surface 12) of the workpiece 10 may be cleaned as well.

According to the context in the present disclosure, a periphery (or a peripheral portion) of a surface refers to a portion of the surface which is different from a central portion and is a peripheral portion being a part of the surface having a certain amount of width including a contour line of the surface. Therefore, if a surface such as the surface 12 is in a circular shape, an outer periphery (or an outer peripheral portion) of the surface has an annular shape with a certain amount of width. Moreover, according to the present disclosure, an outer periphery (or an outer peripheral portion) of a plate member such as the workpiece 10 includes outer peripheries of plane surfaces of the plate member and an outer peripheral surface connecting plane surfaces of the plate member. Therefore, for example, in the case of the workpiece 10, the outer periphery of the workpiece 10 includes the outer periphery of the surface 11, the outer periphery of the surface 12, and the outer peripheral surface connecting the surface 11 and the surface 12.

As described above, the cleaning method performed by the cleaning unit 8 includes a holding step to hold the surface 12 of the workpiece 10 on the holder surface 84 and an outer periphery cleaning step to supply the cleaning fluid 201 from the nozzle 87 to the protruding portion 85 to clean the outer periphery of the surface 12 of the workpiece 10 exposed off the holder surface 84. According to the cleaning unit 8 and the cleaning method, with use of the nozzle 87 that is usable to clean the front surface of the workpiece 10, the back surface (the surface toward the holder surface) may be cleaned as well. Therefore, unlike the known technique, the back surface may be cleaned without providing an additional nozzle while excessive design changes are avoided and the structure of the apparatus is prevented from being complicated.

Moreover, by utilizing the holder surface 84, which is smaller than the workpiece 10 and the existing structure of the cleaning unit, the cleaning unit 8 is enabled solely by the protruding portion 85 provided in the spinner table 83 to clean the back surface.

Moreover, the cleaning unit 8 is configured such that the diameter DB of the holder surface 84 is smaller than the diameter DA of the holder surface 74 of the coating unit 7. Accordingly, the protective layer 100 formed by the coating unit 7 and extended to the back surface is entirely exposed in the cleaning unit 8. Therefore, the protective layer 100 may be removed completely by the cleaning unit 8.

It is preferable that a difference between the diameter DB of the holder surface 84 and the diameter DA of the holder surface 74 is substantially larger than a positioning margin allowed in the conveyer unit, and that the diameter DB of the holder surface 84 is smaller than the diameter DA of the holder surface 74 by twice or more of the positioning margin. For example, in a case where a positioning margin of approximately between 2 mm and 3 mm is allowed, the holder surface 84 shall be smaller than the holder surface 74 by 6 mm or more. By forming the diameter DB of the holder surface 84 to be smaller than the diameter DA of the holder surface 74 by twice or more of the positioning margin, even when an error occurs within the positioning margin at the time of conveyance, the protective layer 100 on the back surface may be removed completely.

Embodiment of the present disclosure may not necessarily be limited to the configurations described above but may be modified, substituted, or altered in various ways without departing from the spirit of the technical idea of the present disclosure. Further, if the technical idea of the present disclosure may be realized in a different way due to technological progress or other derived technology, it may be implemented with use of the method. Therefore, the claims cover all embodiments that may be included within the scope of the technical idea of the present disclosure.

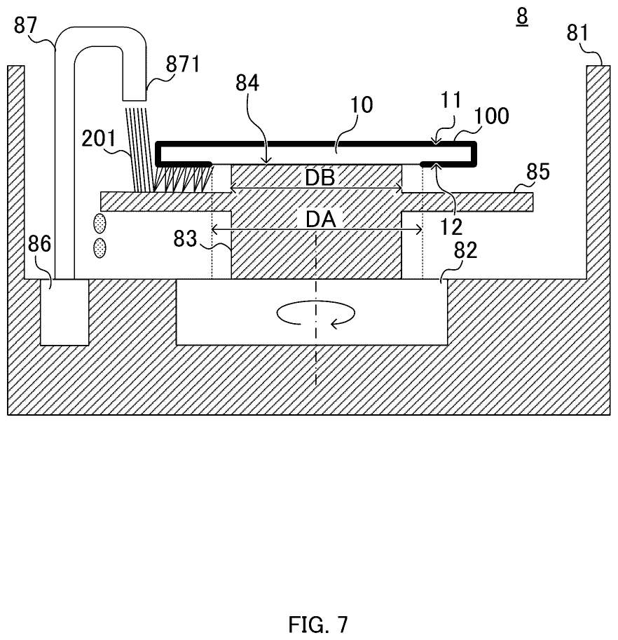

The embodiment described above is an example where the recess portion is filled with the cleaning fluid 201; however, the recess portion may not necessarily be filled with the cleaning fluid 201, as long as the dirt and the protective layer 100 are removable by the cleaning fluid 201 reaching the surface 12. As such, for example, as shown in FIG. 7, the dirt on the surface 12 may be removed by the cleaning fluid 201 bouncing off the protruding portion 85 and hitting the surface 12.

The embodiment described above is an example where the protruding portion 85 extends horizontally from the sideward surface of the spinner table 83; however, the form of the protruding portion 85 may not necessarily be limited to this example. The protruding portion 85 may be in any form that allows easy entry of the cleaning fluid 201 between the protruding portion 85 and the surface 12. For example, in order for the cleaning fluid 201 to easily stay between the protruding portion 85 and the surface 12, the protruding portion 85 may be formed to incline to be higher toward the edge thereof, and/or a rib (upright portion) may be provided at the edge of the protruding portion 85.

The embodiment described above is an example where the holder surface 84 has the round form; however, the form of the holder surface 84 may not necessarily be limited as long as the holder surface 84 is smaller than the workpiece 10 so that a part of the workpiece 10 held by the holder surface 84 protrudes outward from the holder surface 84. Thereby, the part of the workpiece 10 held by the holder surface 84 is exposed to be cleaned by the cleaning unit 8.

The embodiment described above is an example where the front surface (surface 11) and the back surface (surface 12) of the workpiece 10 are cleaned with use of the same nozzle; however, a plurality of cleaning nozzles may be provided, and the front surface and the back surface of the workpiece 10 may be cleaned with the different cleaning nozzles. By cleaning the front surface and the back surface with the different nozzles, the front surface and the back surface may be cleaned simultaneously in parallel.

The embodiment described above is an example where the holder surface 84 faces upward, but the facing direction of the holder surface 84 may not necessarily be limited as long as the protruding portion 85 faces the surface 12 exposed off the holder surface 84. For example, the holder surface 84 may be arranged to face downward or horizontally.

The embodiment described above is an example where the laser unit 4 is the processing unit; however, the processing unit may not necessarily be limited to the laser unit 4. The processing unit may be any unit that processes a workpiece such as cutting unit, grinding unit, or polishing unit.

The embodiment described above is an example where the laser processing apparatus 1 is provided with the laser unit 4, the coating unit 7, and the cleaning unit 8 accommodated in the single housing, but the processing system to process the workpiece 10 may be provided with these units distributed in separate apparatuses.

### INDUSTRIAL APPLICABILITY

As described above, according to the cleaning apparatus, the processing system, and the cleaning method of the present disclosure, the back surface of the workpiece 10 may be cleaned, and therefore useful, as dirt that may otherwise not be removed by cleaning of the front surface alone is removable.

What is claimed is:

1. A cleaning apparatus, comprising:
a first holder surface for holding a first surface of a workpiece, the first holder surface being smaller than the workpiece;
a rotation device configured to support and rotate the first holder surface;
a protruding portion located closer than the first holder surface to the rotation device, the protruding portion protruding outward with respect to the first holder surface; and
a nozzle configured to supply cleaning fluid toward the protruding portion,
wherein the protruding portion is configured to guide the cleaning fluid supplied from the nozzle to enter a gap between the protruding portion and the first surface of the workpiece exposed off the first holder surface to clean an outer periphery of the first surface of the workpiece.

2. A processing system, comprising:
the cleaning apparatus according to claim 1;
a coating unit having a second holder surface, the second holder surface being smaller than the workpiece and configured to hold the first surface of the workpiece, the coating unit being configured to supply a coating agent to a second surface of the workpiece held by the second holder surface and coat the second surface of the workpiece; and
a processing unit configured to process the workpiece, the second surface of which is coated by the coating unit,
wherein the cleaning apparatus is configured to clean the workpiece having been processed by the processing unit, and
wherein the first holder surface of the cleaning apparatus is smaller than the second holder surface of the coating unit.

3. A cleaning method to clean the workpiece with use of the cleaning apparatus according to claim 1, comprising:
holding the first surface of the workpiece on the first holder surface; and
supplying the cleaning fluid from the nozzle to the protruding portion and cleaning the outer periphery of the first surface of the workpiece exposed off the first holder surface.
